(19) United States
(12) Patent Application Publication
(10) Pub. No.: US 2026/0323832 A1
(43) Pub. Date: Oct. 15, 2026

(54) COMPRESSION ATTACH COMPONENT MOUNTING SYSTEM, METHOD AND DEVICE

(71) Applicant: Marvell Asia Pte Ltd, Singapore (SG)

(72) Inventors: Kazin Simon Blacklow, Burlington, VT (US); Joshua F. Dillon, Stowe, VT (US); Zachary Baldwin, Burlington, VT (US); Ting Zheng, San Jose, CA (US); Aatreya Chakravarti, Winooski, VT (US); Wolfgang Sauter, Starksboro, VT (US); Carlos Macian Ruiz, Los Gatos, CA (US); Sidney William Allman, Stittsville (CA); Mark William Kuemerle, Essex Junction, VT (US); Samer Akiki, Redwood City, CA (US)

(21) Appl. No.: 19/643,784

(22) Filed: Apr. 9, 2026

Related U.S. Application Data
(60) Provisional application No. 63/787,515, filed on Apr. 11, 2025.

(51) Int. Cl. H05K 1/18

(52) U.S. Cl. CPC H05K 1/18; H05K 2201/10598

(57) ABSTRACT

A compression attach component mounting system, method and device including a package substrate, a computing package electrically coupled to a top of the package substrate, one or more compression attachment components, a rigid stiffener and one or more fasteners detachably compressing the compression attachment components and the rigid stiffener onto the package substrate such that the compression attachment components electrically couple with the computing package via a circuit of the package substrate.

### RELATED APPLICATIONS

This application claims priority under 35 U.S.C. § 119(e) of the co-pending U.S. provisional patent application Ser. No. 63/787,515 filed Apr. 11, 2025, and titled “Compression attach component mounting using package stiffener,” which is hereby incorporated by reference.

### FIELD OF INVENTION

The present invention relates to compression attach component mounting systems, methods and devices. More particularly, the present invention relates to compression attach component mounting systems, methods and devices including package stiffeners.

### BACKGROUND OF THE INVENTION

Generally, Compression Attached Memory Modules (CAMM) are integrated on a motherboard near an auxiliary processing unit (XPU) module package. This requires lengthy, high loss traces through the board, as well as many ball grid arrays (BGAs) on the package. Further, high loss traces cause higher power consumption and lower speed I/O reducing bandwidth. Additionally, the increased number of BGAs drives up the size of the package increasing cost. Memory modules on the motherboard also increase the size/complexity of the board. Moreover, these modules require backing plates in order to allow threaded screws to compress the module onto the contacts thereby achieving a robust electrical connection.

### BRIEF SUMMARY OF THE INVENTION

A compression attach component mounting system, method and device including a package substrate, a computing package electrically coupled to a top of the package substrate, one or more compression attachment components, a rigid stiffener and one or more fasteners detachably compressing the compression attachment components and the rigid stiffener onto the package substrate such that the compression attachment components electrically couple with the computing package via a circuit of the package substrate.

A first aspect is directed to a compression attach component mounting system. The system comprises a package substrate including a circuit, a computing package electrically coupled to a top of the package substrate, one or more compression attachment components (CACXs), a rigid stiffener and one or more fasteners detachably compressing the CACXs and the rigid stiffener onto the package substrate such that the CACXs electrically couple with the computing package via the circuit of the package substrate. In some embodiments, the rigid stiffener is a ring that surrounds the computing package. In some embodiments, the system further comprises an adapter plate positioned between and electrically coupling together one of the CACXs and the package substrate. In some embodiments, the system further comprises a rigid mounting plate positioned adjacent to one of the CACXs opposite the package substrate such that the one of the CACXs is sandwiched between the mounting plate and the package substrate by the fasteners. In some embodiments, the system further comprises a mezzanine connector electrically coupling a bottom of the package substrate with a surface of a printed circuit board. In some embodiments, each of the fasteners extend through the rigid stiffener, the package substrate and one of the CACXs.

In some embodiments, each of the fasteners extend through the package substrate and one of the CACXs, but only partially into the rigid stiffener. In some embodiments, the CACXs contact the top of the package substrate and the rigid stiffener contacts a bottom of the package substrate. In some embodiments, the CACXs contact a bottom of the package substrate and the rigid stiffener contacts the top of the package substrate. In some embodiments, one or more of the CACXs contact a bottom of the package substrate, a remainder of the CACXs contact the top of the package substrate and the rigid stiffener contacts a surface of one of a group consisting of the one or more of the CACXs and the remainder of the CACXs. In some embodiments, the system further comprises an additional rigid stiffener, wherein one or more of the CACXs contact a bottom of the package substrate, a remainder of the CACXs contact the top of the package substrate, the rigid stiffener contacts a surface of the one or more of the CACXs and the additional rigid stiffener contacts a surface of the remainder of the CACXs.

Another aspect is directed to a compression attach component mount. The mount comprises a package substrate having a top surface, a bottom surface and a thickness between the top surface and the bottom surface in a direction perpendicular to the top surface and the bottom surface, wherein the package substrate includes a circuit, a computing package electrically coupled to the top surface of the package substrate, one or more compression attachment components (CACXs) physically detachably coupled to the package substrate such that the CACXs are electrically coupled with the computing package via the circuit and a rigid stiffener physically detachably coupled with the package substrate and the CACXs, wherein in the direction perpendicular to the top surface and the bottom surface, a perimeter of each of the CACXs and a perimeter of the rigid stiffener overlap. In some embodiments, the rigid stiffener is a ring that surrounds the computing package. In some embodiments, the mount further comprises an adapter plate positioned between and electrically coupling together one of the CACXs and the package substrate. In some embodiments, the mount further comprises one or more fasteners and a rigid mounting plate positioned adjacent to one of the CACXs opposite the package substrate such that the one of the CACXs is sandwiched between the mounting plate and the package substrate by the one or more fasteners.

In some embodiments, the mount further comprises a mezzanine connector electrically coupling a bottom of the package substrate with a surface of a printed circuit board. In some embodiments, the mount further comprises one or more fasteners, wherein each of the fasteners extend through the rigid stiffener, the package substrate and one of the CACXs. In some embodiments, the mount further comprises one or more fasteners, wherein each of the fasteners extend through the package substrate and one of the CACXs, but only partially into the rigid stiffener. In some embodiments, the CACXs contact the top surface of the package substrate and the rigid stiffener contacts the bottom surface of the package substrate. In some embodiments, the CACXs contact the bottom surface of the package substrate and the rigid stiffener contacts the top surface of the package substrate. In some embodiments, one or more of the CACXs contact the bottom surface of the package substrate, a remainder of the CACXs contact the top surface of the package substrate and the rigid stiffener contacts a surface of one of a group consisting of the one or more of the CACXs and the remainder of the CACXs. In some embodiments, the mount further comprises an additional rigid stiffener, wherein one or more of the CACXs contact the bottom surface of the package substrate, a remainder of the CACXs contact the top surface of the package substrate, the rigid stiffener contacts a surface of the one or more of the CACXs and the additional rigid stiffener contacts a surface of the remainder of the CACXs.

Another aspect is directed to a method of providing a compression attach component mounting system. The method comprises providing a package substrate including a circuit, electrically coupling a computing package to a top of the package substrate, providing one or more compression attachment components (CACXs), providing a rigid stiffener and detachably compressing the CACXs and the rigid stiffener onto the package substrate with one or more fasteners such that the CACXs electrically couple with the computing package via the circuit of the package substrate. In some embodiments, the rigid stiffener is a ring that surrounds the computing package. In some embodiments, the method further comprises positioning an adapter plate between one of the CACXs and the package substrate and electrically coupling the adapter plate with the one of the CACXs and the package substrate. In some embodiments, the method further comprises positioning a rigid mounting plate adjacent to one of the CACXs opposite the package substrate such that the one of the CACXs is sandwiched between the mounting plate and the package substrate by the fasteners. In some embodiments, the method further comprises electrically coupling a bottom of the package substrate with a surface of a printed circuit board with a mezzanine connector.

In some embodiments, each of the fasteners extend through the rigid stiffener, the package substrate and one of the CACXs. In some embodiments, each of the fasteners extend through the package substrate and one of the CACXs, but only partially into the rigid stiffener. In some embodiments, the CACXs contact the top of the package substrate and the rigid stiffener contacts a bottom of the package substrate. In some embodiments, the CACXs contact a bottom of the package substrate and the rigid stiffener contacts the top of the package substrate. In some embodiments, one or more of the CACXs contact a bottom of the package substrate, a remainder of the CACXs contact the top of the package substrate and the rigid stiffener contacts a surface of one of a group consisting of the one or more of the CACXs and the remainder of the CACXs. In some embodiments, one or more of the CACXs contact a bottom of the package substrate, a remainder of the CACXs contact the top of the package substrate and the rigid stiffener contacts a surface of the one or more of the CACXs, the method further comprising contacting a surface of the remainder of the CACXs with an additional rigid stiffener.

Another aspect is directed to a compression attach component mounting system. The system comprises means for supporting a package, the means for supporting including a circuit, means for computing electrically coupled to a top of the means for supporting, one or more compression attachment components (CACXs), means for stiffening and one or more fasteners detachably compressing the CACXs and the means for stiffening onto the means for supporting such that the CACXs electrically couple with the means for computing via the circuit of the means for supporting.

### BRIEF DESCRIPTION OF THE DRAWINGS

FIG. 1A illustrates a top view of a compression attach component mount system according to some embodiments.

FIG. 1B illustrates a side cross section view of the compression attach component mount system of FIG. 1A at line A according to some embodiments.

FIG. 2A illustrates a top view of a compression attach component mount system according to some embodiments.

FIG. 2B illustrates a side cross section view of the compression attach component mount system of FIG. 2A at line B according to some embodiments.

FIG. 3A illustrates a top view of a compression attach component mount system according to some embodiments.

FIG. 3B illustrates a side cross section view of the compression attach component mount system of FIG. 3A at line C according to some embodiments.

FIG. 4 illustrates a method of providing a compression attach component mounting system according to some embodiments.

### DETAILED DESCRIPTION OF THE INVENTION

In the following description, numerous details are set forth for purposes of explanation. However, one of ordinary skill in the art will realize that the invention can be practiced without the use of these specific details. Thus, the present invention is not intended to be limited to the embodiments shown but is to be accorded with the widest scope consistent with the principles and features described herein.

Embodiments are directed to a compression attach component mounting system, method and device including a package substrate, a computing package electrically coupled to a top of the package substrate, one or more compression attachment components, a rigid stiffener and one or more fasteners detachably compressing the compression attachment components and the rigid stiffener onto the package substrate such that the compression attachment components electrically couple with the computing package via a circuit of the package substrate.

As a result, the compression attach component mounting system, method and device has the benefit of providing replaceable/repairable components to save expensive system functionality (e.g. enabling a compression attach component to be replaced separately rather than an entire computing module). Further, the use of the stiffener results in saving both real estate and complexity on the printed circuit board and increased package memory capacity. Additionally, due to the proximity of the compression attach components to the processing elements, the system provides shorter and/or lower loss/latency traces which allows memories to run faster and have higher bandwidth and allows the PHY to run at lower power. Moreover, the system provides the potential to reduce package size due to less need for isolation wherein optimized components for this integration scheme could leverage this advantage. Finally, the system enables use of a standard interface for component attachment, wherein such connectors and components are more rigorously tested prior to integration and thus provide known good assembly.

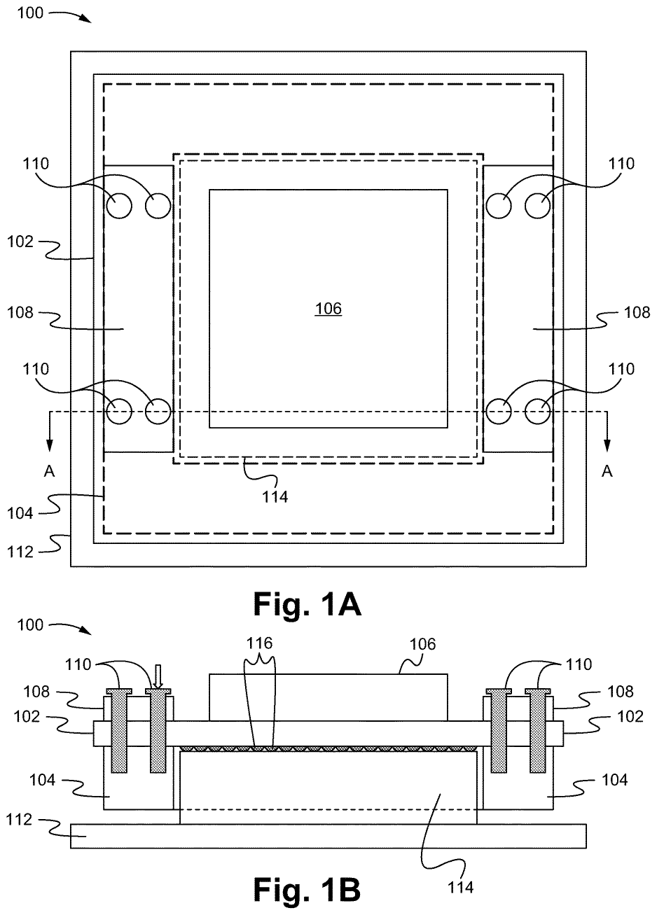

FIGS. 1A and 1B illustrate top and side cross section (at line A) views, respectively, of a compression attach component mount system 100 according to some embodiments. As shown in FIGS. 1A and 1B, the system 100 comprises a package substrate 102, a rigid stiffener 104, a computing package 106, one or more compression attach components (CACX) 108, one or more fasteners 110, a printed circuit board 112 and an offset electrical connector 114. Alternatively, one or more of the components of the system 100 are able to be omitted. The fasteners 110 are able to comprise fully threaded bolts, partially threaded bolts and/or bolt and nut pairs. Alternatively, the fasteners 110 are able to comprise other types of fastening elements (e.g. clamps) that provide the compression forces required (and create a detachable/re-attachable coupling).

The package substrate 102 is able to comprise a high-density insulating layer (e.g. ceramic, organic and/or glass) used to mount, protect, and electrically connect with integrated circuit (IC) chips. The bottom surface of the package substrate 102 is able to have a plurality of electrical contacts 116 (e.g. a ball grid array) and the top surface is able to have one or more circuits (e.g. metal traces, vias, contact pads), with one or more inner layers electrically coupling the electrical contacts 116 with the circuits on the top surface (e.g. via through silicon vias). The electrical contacts 116 are able to cover some or all of the bottom surface of the substrate 102. The circuits on the top surface of the substrate 102 are not shown for the sake of clarity. The substrate 102 is able to comprise one or more through holes for receiving the fasteners 110. The through holes are able to be threaded or unthreaded to correspond to whether the holes of the stiffener 104 are threaded and/or the fasteners are threaded.

The rigid stiffener 104 is able to comprise metal (e.g. copper, stainless steel, aluminum alloys) and/or other rigid materials (e.g. woven glass-fiber epoxy) sufficient to provide structural reinforcement, prevent package warpage, and/or assist with heat dissipation. The rigid stiffener 104 is able to comprise one or more holes for receiving the fasteners 104. In some embodiments, as shown in FIG. 1B, the holes are able to not extend all the way through the stiffener 104 and/or have inner threading. Alternatively, one or more of the holes are able to extend all the way through the stiffener 104 and/or not have inner threading. The holes are able to align with the holes of the substrate 102. Although as shown in FIGS. 1A and 1B, the stiffener 104 comprises a flat frame or ring shape, other shapes are contemplated. For example, the stiffener 104 is able to comprise a flat U-shape, one or more flat L-shapes and/or other shapes known in the art. Similarly, although as shown in FIGS. 1A and 1B, the CACXs 108 comprise a flat rectangular shape, other shapes are contemplated. For example, one or more of the CACXs 108 are able to comprise a flat U-shape, flat ring shape, flat frame shape, flat L-shapes and/or other shapes known in the art. In some embodiments, the CACXs 108 each have a shape having a top-down perimeter that matches or fits within the top-down perimeter of one of the stiffeners 104 that is coupled to that CACX 108 (via the fasteners 110).

The computing or processing package 106 is able to comprise one or more electronic components (e.g. microchips, auxiliary processing units (XPU), application specific integrated circuits (ASIC), passive components and/or other electronic components) configured to communicate with the CACXs 108. For example, in some embodiments the computing package 106 is a high bandwidth memory package (e.g. DRAM stack, XPU, interposer, DRAM ASIC). Alternatively, the computing package 106 is able to comprise other electronic circuits or circuitry. In any case, the computing package 106 is electrically coupled to the circuit (and the electrical contacts 116) of the package substrate 102.

The CACXs 108 are able to comprise one or more of compression attached memory modules (CAMM/CAMM2), Low-Power Compression Attached Memory Modules (LPCAMM/LPCAMM2), Small Outline Compression Attached Memory Modules (SOCAMM/SOCAMM2), and/or other types of modules that are configured to detachably electrically and physically attach to another component (e.g. package substrate) via a compression fastening system. Each of the CACXs 108 is able to comprise one or more through holes for receiving the fasteners 110. The through holes are able to align with the holes of the stiffener 104 and/or substrate 102 and are able to be threaded or unthreaded. The CACXs 108 are able to detachably physically and/or electrically couple to the electrical contacts 116 and/or the circuit of the package substrate 102. Specifically, as shown in FIG. 1A, the fasteners 110 are able to slide through the holes in the CACX 108, the substrate 102 and the stiffener 104 in order to selectively tighten (or release) the amount the components are pressed against each other.

For example, when the fasteners 110 and/or the holes are threaded, the fasteners are able to be rotated such that inner threading compresses the CACXs 108 against a top surface of the substrate 102 and the stiffener 104 against a bottom surface of the substrate 102. Alternatively, when the holes lack inner threading, the fasteners 110 are able to comprise pairs of nuts and bolts, wherein the bolt extends from one side through to the other side such that the nut is able to tighten onto the bolt thereby compressing the CACXs 108 against a top surface of the substrate 102 and the stiffener 104 against a bottom surface of the substrate 102. In any case, the coupling/compressing is able to be selectively reversed when decoupling is desired (and reinstated when coupling/compressing is again desired). As a result, electrical contact pads on the CACX 108 contact the circuit on the top of the substrate 102 thereby forming a detachable electrical coupling between the two. Thus, because the circuit is also electrically coupled with the computing package 106, the computing package 106 and the CACXs 108 are able to electrically communicate.

Consequently, the system 100 provides the benefit of preserving detachability of the CACXs 108, thereby making the components replaceable/repairable which saves expensive system functionality (e.g. enabling a compression attach component to be replaced separately rather than an entire computing module). Further, the use of the stiffener 104 as a part of the compression results in saving footprint/real estate and complexity on the package 102 as well as providing increased package 102 memory capacity. Additionally, due to the proximity of the compression attach components 108 to the processing elements 106, the system 100 enables the use of shorter and/or lower loss/latency traces of the circuit on the substrate 102 (between the components 108 and the processing elements 106) which allows memories to run faster and have higher bandwidth and allows the PHY to run at lower power.

The printed circuit board 112 is able to be formed of fiberglass (e.g. FR-4) and comprise another circuit (not shown) formed via conductive traces and other electrical components. The offset electrical connector 114 is able to comprise a body that creates an offset and one or more electrical pathways that extend from a top of the connector 114 to the bottom of the connector 114. In some embodiments, the offset electrical connector 114 is a mezzanine connector. Alternatively, the offset electrical connector 114 is able to comprise other types of electrical connectors. The offset electrical connector 114 is able to detachably electrically and/or physically couple to the electrical contacts 116 on the bottom of the package substrate 102 and the electrical circuit on the top of the printed circuit board 112. As a result, the connector 114 facilitates communication between the circuit of the printed circuit board 112, the circuit of the package substrate 102 (and the other components electrically coupled thereto as described herein).

Although as shown in FIGS. 1A and 1B, the system 100 comprises two CACXs 108, a single stiffener 104 and eight fasteners 110, more or less CACXs 108, stiffeners 104 and/or fasteners 110 are able to be used. Similarly, although FIG. 1A illustrates a first set of locations where the fasteners 110 are able to couple the CACXs 108 and/or stiffener 104 to the substrate 102, any other locations where those three components are aligned from the top view direction are able to be used. In FIG. 1B, the depth of components has been exaggerated for the sake of clarity.

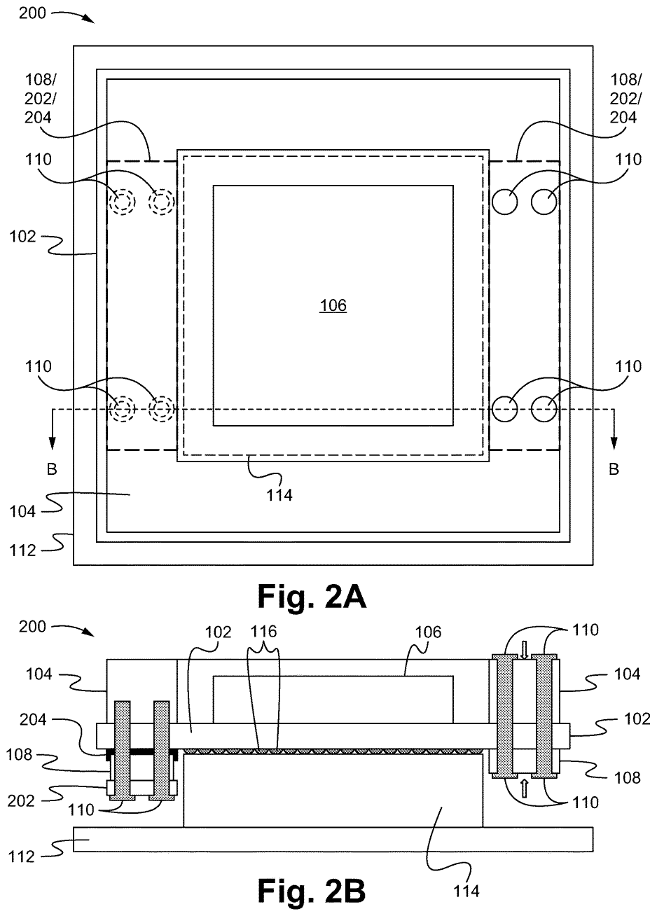

FIGS. 2A and 2B illustrate top and side cross section (at line B) views, respectively, of a compression attach component mount system 200 according to some embodiments. The system 200 is substantially similar to the system 100 except for the differences described herein. Specifically, as shown in FIGS. 2A and 2B, the stiffener 104 is positioned on the top side of the package substrate 102, the CACXs 108 are positioned on the bottom side of the package substrate 102 and one set of the fasteners 110 extend fully through the stiffener 104 (e.g. with a bolt on one end extending through and coupling with a nut on the opposite end). Further as shown in FIGS. 2A and 2B, the system 200 also comprises one or more mounting plates 202 and one or more electrical adapter components 204. In some embodiments, the system 200 comprises a separate mounting plate 202 and/or electrical adapter component 204 for each CACX 108. Alternatively, the system 200 is able to comprise less or more mounting plates 202 and/or electrical adapter components 204.

The mounting plate 202 is able to be positioned against an outer surface of one or more of the CACXs 108 for providing additional structural support to the CACXs 108. Like the CACXs 108 and the stiffener 104, each mounting plate 202 comprises one or more holes (threaded or unthreaded) that align with the holes of the CACXs 108 and/or stiffener 104 such that the fasteners 110 are able to extend through the holes of the mounting plates 202 and detachably compress the mounting plates 202 against the outer surfaces of the CACXs 108. In some embodiments, the mounting plates 202 are formed of the same material as the stiffener 104. Alternatively, the mounting plates 202 are able to be formed of other sufficiently rigid materials.

The electronic adapter component 204 is able to be positioned between the inner surface of one or more of the CACXs 108 and the package substrate 102 for electrically coupling the CACXs 108 with the package substrate 102. In particular, when the electrical contacts of one or more of the CACXs 108 are not configured to correctly electrically couple with the electrical contacts of the substrate 102, the adapter components 204 are able to facilitate the electrical connection by having one side configured to couple with contacts of the CACXs 108 and an opposite side configured to couple with the electrical contacts of the substrate 102. Like the CACXs 108, the stiffener 104 and the mounting plates 202, each electronic adapter component 204 comprises one or more holes (threaded or unthreaded) that align with the holes of the CACXs 108, mounting plates 202 and/or stiffener 104 such that the fasteners 110 are able to extend through the holes of the adapter components 204, the CACXs 108, the substrate 102, the stiffener 104 and/or the mounting plates 202 and detachably compress the electronic adapter components 204 against the inner surfaces of the CACXs 108 and the surface of the package substrate 102.

Although as shown in FIGS. 2A and 2B, the mounting plates 202 are used in conjunction with the electronic adapter components 204, the mounting plates 202 and/or electronic adapter components 204 are able to be used independent of each other (e.g. a CACX 108 coupled with just a mounting plate 202 or just an adapter component 204, not both). Also although only illustrated in FIGS. 2A and 2B, the mounting plates 202 are able to be combined with any of the systems 100, 200, 300 described herein in the same manner as described in relation to FIGS. 2A and 2B (e.g. wherein the mounting plates 202 are coupled to an outer surface of one or more of the CACXs 108 by the fasteners 110). Similarly, although only illustrated in FIGS. 2A and 2B, the electrical adapter components 204 are able to be combined with any of the systems 100, 200, 300 described herein in the same manner as described in relation to FIGS. 2A and 2B (e.g. with the adapter components 204 positioned/electrically coupled between the inner surface of one or more of the CACXs 108 and the package substrate 102 by the fasteners 110).

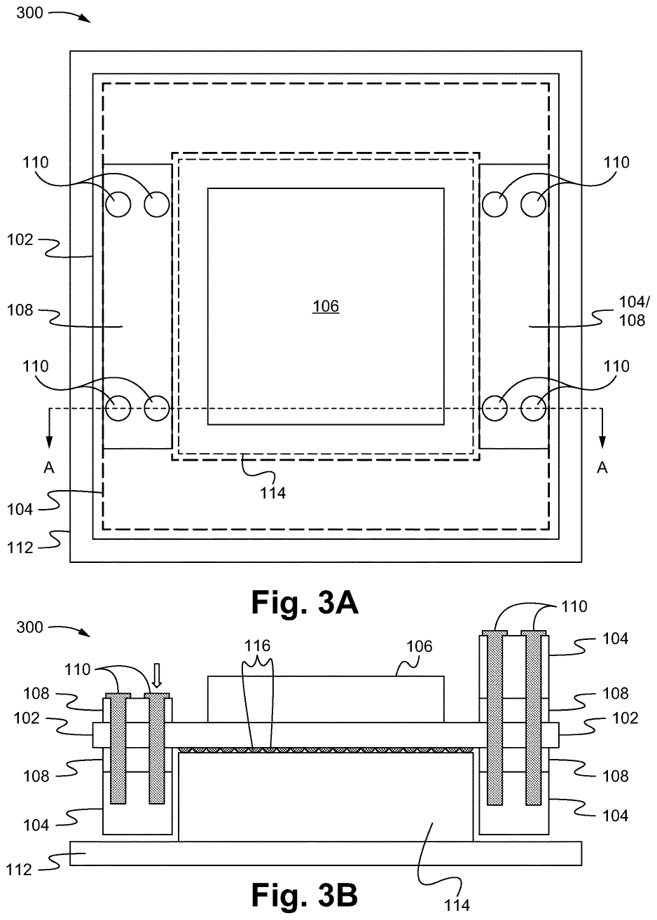

FIGS. 3A and 3B illustrate top and side cross section (at line C) views, respectively, of a compression attach component mount system 300 according to some embodiments. The system 300 is substantially similar to the system 100 except for the differences described herein. Specifically, as shown in FIGS. 3A and 3B, the CACXs 108 are positioned both on the top side and the bottom side of the package substrate 102 and one or more of the stiffeners 104 are able to be positioned adjacent to an outer surface of one or more of the CACXs 108 (instead of the surface of the substrate 102). The fasteners 110 are able to extend through and/or into the stack of one or more CACXs 108, one or more stiffeners 104 and the substrate 102 in order to detachably compress the stack together. Thus, the system 300 provides the benefit of increasing the number of CACXs 108 coupled to the substrate 102 while still maintaining the anti-warpage and small footprint of the CACXs 108 and/or stiffeners 104 on the substrate 102.

In some embodiments, as shown in FIG. 3A, one or more of the stiffeners 104 positioned on the top side of the substrate 102 (e.g. the same side as the processing elements 106) are able to have a same or similar top-down perimeter as the CACX 108 to which they are coupled. Alternatively, one or more of the stiffeners 104 positioned on the top side of the substrate 102 are able to have a larger or smaller top-down perimeter than the CACX 108 to which they are coupled. Although as shown in FIGS. 3A and 3B the system 300 comprises four CACXs 108 and two rigid stiffeners 104, the system 300 is able to comprise more or less CACXs 108 and/or stiffeners 104.

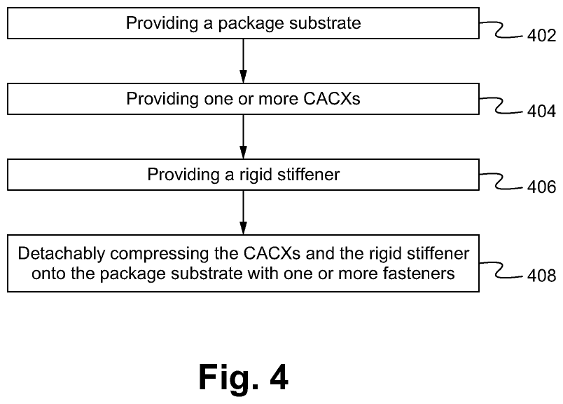

FIG. 4 illustrates a method of providing a compression attach component mounting system 100, 200, 300 according to some embodiments. As shown in FIG. 4, a package substrate 102 is provided at the step 402. The package substrate 102 includes a circuit, electrically coupling a computing package 106 to a top of the package substrate 102. One or more CACXs 108 are provided at the step 404. A rigid stiffener 104 is provided at the step 406. The CACXs 108 and the rigid stiffener 104 are detachably compressed onto the package substrate 102 with one or more fasteners 110 at the step 406. In particular, the detachable compression is able to be such that the CACXs 108 electrically couple with the computing package 106 via the circuit of the package substrate 102. In some embodiments, the method further comprises positioning an adapter 204 between one of the CACXs 108 and the package substrate 102 and electrically coupling the adapter 204 with the one of the CACXs 108 and the package substrate 102. In some embodiments, the method further comprises positioning a mounting plate 202 adjacent to one of the CACXs 108 opposite the package substrate 102 such that the one of the CACXs 108 is sandwiched between the mounting plate 202 and the package substrate 102 by the fasteners 110.

In some embodiments, the method further comprises electrically coupling a bottom of the package substrate 102 with a surface of a printed circuit board 112 with a mezzanine connector 114. In some embodiments, the method further comprises contacting an outer surface of one or more of the CACXs 108 with an additional rigid stiffener 104 and coupling the additional rigid stiffener 104 to the one or more of the CACXs 108 with the fasteners 110. In some embodiments, coupling using the fasteners 110 comprises extending one or more of the fasteners 110 into and/or through aligned holes of one or more rigid stiffeners 104, the package substrate 102, one or more of the CACXs 108, one or more adapters 204, and/or one or more mounting plates 202, and then securing the fasteners 110 within the holes via threading (found in the holes and/or on the fastener) or via coupling another component of the fasteners 110 (e.g. threadably coupling to a nut) that couples to the portion of the fasteners 110 extending out of the holes opposite where it entered the holes.

The compression attach component mounting system, method and device described herein provides numerous advantages. Specifically, the system, method and device has the benefit of providing replaceable/repairable components to save expensive system functionality (e.g. enabling a compression attach component to be replaced separately rather than an entire computing module). Further, the use of the stiffener 104 as a part of the compression results in saving both real estate and complexity on the package 102 and increased package memory capacity. Additionally, due to the proximity of the compression attach components 108 to the processing elements 106, the system 100 enables the use of shorter and/or lower loss/latency traces of the circuit on the substrate 102 (between the components 108 and the processing elements 106) which allows memories to run faster and have higher bandwidth and allows the PHY to run at lower power. Moreover, the system 100 provides the potential to reduce package size due to less need for isolation wherein optimized components for this integration scheme could leverage this advantage. Finally, the system enables use of a standard interface for component attachment, wherein such connectors and components are more rigorously tested prior to integration and thus provide known good assembly.

While the system, method and device has been described with reference to numerous specific details, one of ordinary skill in the art will recognize that the invention can be embodied in other specific forms without departing from the spirit of the invention. For example, although as illustrated in the FIGS. 1A-3B, the CACXs 108 are positioned on the right or left side of the substrate 102, it is understood that one or more of the CACXs 108 are able to be positioned on the front, the back, the corner, other position and/or combination of positions on the top or bottom side of the substrate 102 (as long as the top-down perimeter of the CACXs 108 are aligned with or within the top-down perimeter of one of the stiffeners 104 coupled thereto by the fasteners 110). Similarly, although the systems 100, 200 and 300 are described separately, the configurations of components of the systems 100, 200 and 300 are able to be combined (e.g. the left side configured as shown in FIGS. 1A and 1B and a right side configured as in FIGS. 2A and 2B; front configured as shown in FIGS. 3A and 3B, left and right configured as shown in FIGS. 1A and 1B; or any other combination of the systems). Finally, although the systems 100, 200, 300 are described as utilizing detachable coupling/compressing, it is understood that the coupling (and/or the type of fasteners 110 used) are able to implement a permanent coupling of one or more of the components described above as being coupled together. Thus, one of ordinary skill in the art will understand that the invention is not to be limited by the foregoing illustrative details.

Further, it should be noted that although not described in detail for the sake of brevity, the systems 100, 200, 300 and/or the parts thereof (e.g. computing package 106, package substrate 102, PCB 112, connector 114, and/or CACXs 108) are able to include or be a part of one or more of an integrated circuit, an ASIC, a high bandwidth memory module, an AI accelerator, a software defined network, a top of rack switch, a network interface, additional memory, additional processors, I/O device(s), buses and/or a storage device. The additional memory of the systems 100, 200, 300 and/or parts thereof is able to be any conventional computer memory known in the art such as, but not limited to, a hard drive, DRAM, RAM, SRAM, CDROM, CDRW, DVD, DVDRW, flash memory card or any other storage device. An example of a network interface includes a network card connected to an Ethernet or other type of LAN. The I/O device(s) are able to include one or more of the following: keyboard, mouse, monitor, display, printer, modem, touchscreen, button interface and other devices. An operating system(s), graphical user interface(s), application(s), module(s) and/or other software on the system 100 (and/or parts thereof) are able to be stored in the memory and/or additional memory and/or storage device and processed as software is typically processed via the processors and/or additional processors of the systems 100, 200, 300. The processes are able to be implemented via hardware, software, firmware and/or a combination of two or more of hardware, software and firmware such as memory, software/firmware and/or processors to execute the software/firmware stored on the memory in order to perform the functions of the processes.

We claim:

1. A compression attach component mounting system, the system comprising:
a package substrate including a circuit;
a computing package electrically coupled to a top of the package substrate;
one or more compression attachment components (CACXs);
a rigid stiffener; and
one or more fasteners detachably compressing the CACXs and the rigid stiffener onto the package substrate such that the CACXs electrically couple with the computing package via the circuit of the package substrate.

2. The system of claim 1, wherein the rigid stiffener is a ring that surrounds the computing package.

3. The system of claim 1, further comprising an adapter plate positioned between and electrically coupling together one of the CACXs and the package substrate.

4. The system of claim 1, further comprising a rigid mounting plate positioned adjacent to one of the CACXs opposite the package substrate, such that the one of the CACXs is sandwiched between the mounting plate and the package substrate by the fasteners.

5. The system of claim 1, further comprising a mezzanine connector electrically coupling a bottom of the package substrate with a surface of a printed circuit board.

6. The system of claim 1, wherein each of the fasteners extend through the rigid stiffener, the package substrate and one of the CACXs.

7. The system of claim 1, wherein each of the fasteners extend through the package substrate and one of the CACXs, but only partially into the rigid stiffener.

8. The system of claim 1, wherein the CACXs contact the top of the package substrate and the rigid stiffener contacts a bottom of the package substrate.

9. The system of claim 1, wherein the CACXs contact a bottom of the package substrate and the rigid stiffener contacts the top of the package substrate.

10. The system of claim 1, wherein one or more of the CACXs contact a bottom of the package substrate, a remainder of the CACXs contact the top of the package substrate and the rigid stiffener contacts a surface of one of a group consisting of the one or more of the CACXs and the remainder of the CACXs.

11. The system of claim 1, further comprising an additional rigid stiffener, wherein one or more of the CACXs contact a bottom of the package substrate, a remainder of the CACXs contact the top of the package substrate, the rigid stiffener contacts a surface of the one or more of the CACXs and the additional rigid stiffener contacts a surface of the remainder of the CACXs.

12. A compression attach component mount, the mount comprising:
a package substrate having a top surface, a bottom surface and a thickness between the top surface and the bottom surface in a direction perpendicular to the top surface and the bottom surface, wherein the package substrate includes a circuit;
a computing package electrically coupled to the top surface of the package substrate;
one or more compression attachment components (CACXs) physically detachably coupled to the package substrate such that the CACXs are electrically coupled with the computing package via the circuit; and
a rigid stiffener physically detachably coupled with the package substrate and the CACXs,
wherein in the direction perpendicular to the top surface and the bottom surface, a perimeter of each of the CACXs and a perimeter of the rigid stiffener overlap.

13. The mount of claim 12, wherein the rigid stiffener is a ring that surrounds the computing package.

14. The mount of claim 12, further comprising an adapter plate positioned between and electrically coupling together one of the CACXs and the package substrate.

15. The mount of claim 12, further comprising one or more fasteners and a rigid mounting plate positioned adjacent to one of the CACXs opposite the package substrate such that the one of the CACXs is sandwiched between the mounting plate and the package substrate by the one or more fasteners.

16. The mount of claim 12, further comprising a mezzanine connector electrically coupling a bottom of the package substrate with a surface of a printed circuit board.

17. The mount of claim 12, further comprising one or more fasteners, wherein each of the fasteners extend through the rigid stiffener, the package substrate and one of the CACXs.

18. The mount of claim 12, further comprising one or more fasteners, wherein each of the fasteners extend through the package substrate and one of the CACXs, but only partially into the rigid stiffener.

19. The mount of claim 12, wherein the CACXs contact the top surface of the package substrate and the rigid stiffener contacts the bottom surface of the package substrate.

20. The mount of claim 12, wherein the CACXs contact the bottom surface of the package substrate and the rigid stiffener contacts the top surface of the package substrate.

21. The mount of claim 12, wherein one or more of the CACXs contact the bottom surface of the package substrate, a remainder of the CACXs contact the top surface of the package substrate and the rigid stiffener contacts a surface of one of a group consisting of the one or more of the CACXs and the remainder of the CACXs.

22. The mount of claim 12, further comprising an additional rigid stiffener, wherein one or more of the CACXs contact the bottom surface of the package substrate, a remainder of the CACXs contact the top surface of the package substrate, the rigid stiffener contacts a surface of the one or more of the CACXs and the additional rigid stiffener contacts a surface of the remainder of the CACXs.

23. A method of providing a compression attach component mounting system, the method comprising:
providing a package substrate including a circuit;
electrically coupling a computing package to a top of the package substrate;
providing one or more compression attachment components (CACXs);
providing a rigid stiffener; and
detachably compressing the CACXs and the rigid stiffener onto the package substrate with one or more fasteners such that the CACXs electrically couple with the computing package via the circuit of the package substrate.

24. The method of claim 23, wherein the rigid stiffener is a ring that surrounds the computing package.

25. The method of claim 23, further comprising:
positioning an adapter plate between one of the CACXs and the package substrate; and
electrically coupling the adapter plate with the one of the CACXs and the package substrate.

26. The method of claim 23, further comprising positioning a rigid mounting plate adjacent to one of the CACXs opposite the package substrate such that the one of the CACXs is sandwiched between the mounting plate and the package substrate by the fasteners.

27. The method of claim 23, further comprising electrically coupling a bottom of the package substrate with a surface of a printed circuit board with a mezzanine connector.

28. The method of claim 23, wherein each of the fasteners extend through the rigid stiffener, the package substrate and one of the CACXs.

29. The method of claim 23, wherein each of the fasteners extend through the package substrate and one of the CACXs, but only partially into the rigid stiffener.

30. The method of claim 23, wherein the CACXs contact the top of the package substrate and the rigid stiffener contacts a bottom of the package substrate.

31. The method of claim 23, wherein the CACXs contact a bottom of the package substrate and the rigid stiffener contacts the top of the package substrate.

32. The method of claim 23, wherein one or more of the CACXs contact a bottom of the package substrate, a remainder of the CACXs contact the top of the package substrate and the rigid stiffener contacts a surface of one of a group consisting of the one or more of the CACXs and the remainder of the CACXs.

33. The method of claim 23, wherein one or more of the CACXs contact a bottom of the package substrate, a remainder of the CACXs contact the top of the package substrate and the rigid stiffener contacts a surface of the one or more of the CACXs, further comprising contacting a surface of the remainder of the CACXs with an additional rigid stiffener.

34. A compression attach component mounting system, the system comprising:
means for supporting a package, the means for supporting including a circuit;
means for computing electrically coupled to a top of the means for supporting;
one or more compression attachment components (CACXs);
means for stiffening; and
one or more fasteners detachably compressing the CACXs and the means for stiffening onto the means for supporting such that the CACXs electrically couple with the means for computing via the circuit of the means for supporting.
